(19) United States
(12) Patent Application Publication
(10) Pub. No.: US 2018/0285706 A1
(43) Pub. Date: Oct. 4, 2018

(54) Electronic Device Having an Antenna, Metal Trace(s) and/or Inductor With a Printed Adhesion Promoter Thereon, and Methods of Making and Using the Same

(71) Applicant: Thin Film Electronics ASA, Oslo (NO)

(72) Inventors: Mao TAKASHIMA, Cupertino, CA (US); Jacob BOYD, San Jose, CA (US); Aditi CHANDRA, Los Gatos, CA (US)

(21) Appl. No.: 15/765,885

(22) PCT Filed: Oct. 6, 2015
(86) PCT No.: PCT/US2016/055817

§ 371 Date: Apr. 4, 2018

Related U.S. Application Data
(60) Provisional application No. 62/238,045, filed on Oct. 6, 2015.

(51) Int. Cl. G06K 19/07; H01Q 1/22; H01Q 7/00; H05K 1/16; H05K 3/12; H05K 3/36; G08B 13/24

(52) U.S. Cl. CPC G06K 19/07; H01Q 1/2225; H01Q 7/005; G08B 13/24; H05K 3/12; H05K 3/36; H05K 1/16

(57) ABSTRACT

An electronic device and methods of manufacturing the same are disclosed. One method of manufacturing the electronic device includes forming a first metal layer on a first substrate, forming an electrical device on a second substrate, forming electrical connectors on input and/or output terminals of the electrical device, selectively depositing a second metal on at least part of the first metal layer, and electrically connecting the electrical connectors to the first metal layer by contacting the electrical connectors to the second metal. The second metal is different from the first metal. The second metal improves adhesion and/or electrical connectivity of the first metal layer to the electrical connectors on the electrical device.

### CROSS REFERENCE TO RELATED APPLICATION

This application claims the benefit of U.S. Provisional Pat. Appl. No. 62/238,045, filed on Oct. 6, 2015, incorporated herein by reference as if fully set forth herein.

### FIELD OF THE INVENTION

The present invention generally relates to the field(s) of printed and/or thin film electronic devices, and in some embodiments, to wireless communications and wireless devices. Embodiments of the present invention pertain to radio frequency (RF and/or RFID), near field communication (NFC), high frequency (HF), very high frequency (VHF), ultra high frequency (UHF), and electronic article surveillance (EAS) tags and devices having a layer of palladium or other adhesion-promoting metal or alloy printed on an antenna, metal trace(s), and/or inductor to improve adhesion, electrical connectivity, and/or attachment of the antenna, metal trace(s), and/or inductor to other electrical circuitry in the tag or device, and methods of manufacturing and using the same.

### DISCUSSION OF THE BACKGROUND

Generally, etched aluminum foil on a plastic (e.g., PET) film in backplanes of smart labels, or as antennas, metal traces and/or inductors in EAS and NFC devices, is in use due to the relatively low expense of such materials and processing. However, methods of assembling an aluminum antenna or trace to an integrated circuit or a discrete device (which may be on another substrate) is generally limited to techniques that use stud bumps and/or anisotropic conductive paste (ACP).

Smart labels consist of a variety of components, such as a printed integrated circuit (PIC), a battery, and/or a display. Assembling conventional smart labels requires a variety of surface mounting (e.g., SMD, or “surface mounted device”) techniques and materials, such as anisotropic conductive paste (ACP) and/or soldering.

Conventional printed backplanes may not meet resistivity requirements for high quality (Q) near field communication (NFC) labels, due to their limited thickness. Having a conventionally etched aluminum foil on a plastic film may provide relatively high Q NFC labels. However, the method of assembling an IC and a backplane with an aluminum trace is limited to the use of stud bumps and/or ACPs.

Typically, an etched copper foil on a plastic film, or an etched aluminum foil covered with a copper layer, provides a high Q NFC device that can be assembled using a variety of assembly techniques. However, copper is relatively expensive and is not compatible with food products.

Conventionally, discrete devices or integrated circuits can be attached to a backplane by soldering, using metals such as copper, aluminum-plated copper, or tin. Although solder is relatively inexpensive and suitable for large volume manufacturing processes, copper and/or plated aluminum involves additional cost.

Palladium is a useful metal for forming electrical contacts. For example, a palladium ink formulation can be used to print a seed layer (e.g., for a subsequent electroless plating process) or to form a contact metal and/or a silicide. However, palladium is also expensive, and its use and/or capability as an adhesive material for assembling inexpensive aluminum antennas and/or metal traces to discrete devices or integrated circuits is not known.

This “Discussion of the Background” section is provided for background information only. The statements in this “Discussion of the Background” are not an admission that the subject matter disclosed in this “Discussion of the Background” section constitutes prior art to the present disclosure, and no part of this “Discussion of the Background” section may be used as an admission that any part of this application, including this “Discussion of the Background” section, constitutes prior art to the present disclosure.

### SUMMARY OF THE INVENTION

The present invention relates to printed and/or thin film electronic devices, more specifically wireless communications and wireless devices. Embodiments of the present invention pertain to radio frequency (RF and/or RFID), near field communication (NFC), high frequency (HF), very high frequency (VHF), ultra high frequency (UHF), and electronic article surveillance (EAS) tags and devices having a selectively deposited layer of palladium or other adhesion-promoting metal or alloy on an antenna, metal trace(s), and/or inductor to improve adhesion, electrical connectivity, and/or attachment of the antenna, metal trace(s), and/or inductor to other electrical circuitry in the tags or devices, and methods of manufacturing and using the same.

In one aspect, the present invention relates to a method of manufacturing an electronic device, comprising forming a first metal layer on a first substrate, forming an electrical device on a second substrate, forming electrical connectors on input and/or output terminals of the electrical device, selectively depositing a second metal on at least part of the first metal layer, and electrically connecting the electrical connectors to the first metal layer by contacting the electrical connectors to the second metal. The second metal is different from the first metal, and improves adhesion and/or electrical connectivity of the first metal layer to the electrical connectors on the electrical device. The electronic device may be a wireless communication device.

In exemplary embodiments of the present invention, the electronic device is a wireless communication device. The wireless communication device may comprise a near field (NFC), radio frequency (RF), high frequency (HF), very high frequency (VHF), or ultra high frequency (UHF) communication device. In some embodiments, the electrical device may include a capacitor. In other embodiments, the electrical device may include an integrated circuit.

In various embodiments of the present invention, the first substrate may include a plastic film. The plastic film may be a polyimide, a glass/polymer laminate, or a high temperature polymer. The high temperature polymer may include polyethylene terephthalate (PET), polypropylene, or polyethylene naphthalate (PEN).

In some embodiments of the present invention, forming the first metal layer may include depositing an aluminum layer on the first substrate. The aluminum layer may have a thickness of at least 10 μm. In further embodiments, the aluminum layer may be etched to form an antenna, one or more metal trace(s), and/or an inductor. In various embodiments of the present invention, forming the first metal layer comprises printing a first ink that includes a seed metal on the first substrate in a pattern corresponding to an antenna, one or more metal trace(s) and/or an inductor. In further embodiments, a bulk metal may be electroplated or electrolessly plated on the printed seed metal, wherein at least one of the bulk metal and the seed metal is the first metal.

In exemplary embodiments, selectively depositing the second metal may include printing a second ink. The second ink may include the second metal or a precursor thereof on parts of the first metal layer to which the electrical connectors are to be electrically connected. The second ink may be printed on predetermined areas of the first metal layer. In some embodiments, the second metal comprises palladium.

In various embodiments of the present invention, the first ink may be dried, and the second metal may be cured. Curing the second metal may include heating the second metal in a reducing atmosphere, which may include a forming gas. The second metal may be heated to a temperature of 100° C. to 250° C.

In exemplary embodiments of the present invention, a third metal may be electrolessly plated on the second metal. In some embodiments, the third metal comprises include nickel, copper, tin, silver, gold, or a combination thereof.

In exemplary embodiments of the present invention, the antenna is configured to (i) receive and (ii) transmit or broadcast wireless signal. The antenna, metal trace(s) and/or inductor consists of a single metal layer on the first substrate.

In various embodiments of the present invention, forming the integrated circuit may include printing one or more layers of the integrated circuit on the second substrate. In some embodiments, a plurality of the layers of the integrated circuit may be printed. Forming the integrated circuit further may include forming one or more additional layers of the integrated circuit by one or more thin film processing techniques. In some embodiments, a plurality of the layers of the integrated circuit may be formed by thin film processing techniques.

In further embodiments, input and/or output terminals may be formed in an uppermost metal layer of the integrated circuit. The input and/or output terminals may include antenna connection pads. In various embodiments, the electrical connectors comprise a first solder bump or solder ball on a first one of the input/output terminals, and a second solder bump or solder ball on a second one of the input/output terminals. The electrical connectors may be electrically connected to the first metal layer by heating and pressing the first and second solder bumps or solder balls to the second metal.

In another aspect, the present invention relates to an electronic device, comprising a substrate having a first metal layer thereon, an electrical device on a second substrate, the electrical device having input and/or output terminals and electrical connectors thereon, the electrical connectors being electrically connected to the first metal, and a second metal layer on at least part of the first metal layer. The electrical connectors are electrically connected to the second metal layer. The second metal layer is configured to improve the adhesion and/or electrical connectivity of the first metal layer to the electrical connectors on the electrical device. The first metal layer may comprise an antenna, and the electronic device may be a wireless communication device.

In exemplary embodiments of the present invention, the electronic device comprises a wireless communication device. The wireless communication device may be a near field (NFC), radio frequency (RF), high frequency (HF), very high frequency (VHF), or ultra high frequency (UHF) communication device. In various embodiments, the electrical device may include a discrete device. In some embodiments, the electrical device may include a capacitor. In other embodiments, the electrical device may include an integrated circuit.

In various embodiments, the first substrate may include a plastic film. The plastic film may be selected from the group consisting of a polyimide, a glass/polymer laminate, or a high temperature polymer. As for the method, the high temperature polymer may include polyethylene terephthalate (PET), polypropylene, or polyethylene naphthalate (PEN). In addition, the second substrate may include a metal foil. The metal foil may include a stainless steel foil or a plastic material. The plastic material may include polyethylene terephthalate (PET), polypropylene, or polyethylene naphthalate (PEN).

As for the method, the first metal layer may include an aluminum layer, which may have a thickness of at least 10 μm. The first metal layer may include an antenna configured to (i) receive and (ii) transmit or broadcast wireless signals. In various embodiments, the antenna, metal trace(s) and/or inductor may consist of a single metal layer.

In various embodiments, the second metal may include palladium (e.g., printed palladium). In further embodiments, a third metal may be on the second metal. The third metal may include nickel, copper, tin, silver, gold, or a combination thereof.

In exemplary embodiments of the present invention, the integrated circuit may include a receiver and a transmitter, in which the transmitter comprises a modulator and the receiver comprises a demodulator. In various embodiments, the integrated circuit may include one or more printed layers. For example, the integrated circuit may include a plurality of printed layers. In further embodiments, the integrated circuit may include one or more thin films. For example, the integrated circuit may include a plurality of thin films.

In various embodiments of the present invention, the input and/or output terminals may be in an uppermost metal layer of the integrated circuit. The input and/or output terminals may include antenna connection pads. The antenna connection pads may include aluminum, tungsten, copper, silver, or a combination thereof. In addition, the electrical connectors may include a first solder bump or solder ball on a first one of the input and/or output terminals, and a second solder bump or solder ball on a second one of the input and/or output terminals. In some embodiments, an adhesive may be on the first and second input/output terminals and the first and second solder bumps or solder balls.

The present invention advantageously improves the mechanical smoothness of an antenna, metal trace(s), and/or inductor on a backplane, as well as the electrical contact between electronic devices, such as thin film or integrated circuitry, and the antenna, trace, and/or inductor. Additionally, the present invention reduces the cost and processing time of certain electronic devices and/or wireless tags, such as smart labels and NFC, RF, HF, and UHF tags, and is compatible with food products. Furthermore, the present invention advantageously enables various attachment techniques, such as solder bumps on an antenna, metal trace(s), and/or inductor and/or a direct solder attachment, without the use of an organic copper protector (OCP) or an anisotropic conductive paste (ACP). These and other advantages of the present invention will become readily apparent from the detailed description of various embodiments below.

### BRIEF DESCRIPTION OF THE DRAWINGS

FIG. 1 shows a flow chart for an exemplary process for making electronic devices (e.g., wireless communication devices) having a printed palladium layer or other adhesion-promoting metal or alloy on an antenna, metal trace(s), and/or inductor, in accordance with one or more embodiments of the present invention.

FIGS. 2A-2E show cross-sectional and plan views of exemplary intermediates in the exemplary process, and FIGS. 2F-2G show plan and cross-sectional views of an exemplary electronic device having a printed palladium layer or other adhesion-promoting metal or alloy on an antenna, in accordance with one or more embodiments of the present invention.

FIGS. 3A-3C show exemplary resonant circuits for use in various electronic devices according to the present invention.

### DETAILED DESCRIPTION

Reference will now be made in detail to various embodiments of the invention, examples of which are illustrated in the accompanying drawings. While the invention will be described in conjunction with the following embodiments, it will be understood that the descriptions are not intended to limit the invention to these embodiments. On the contrary, the invention is intended to cover alternatives, modifications and equivalents that may be included within the spirit and scope of the invention. Furthermore, in the following detailed description, numerous specific details are set forth in order to provide a thorough understanding of the present invention. However, it will be readily apparent to one skilled in the art that the present invention may be practiced without these specific details. In other instances, well-known methods, procedures, components, and materials have not been described in detail so as not to unnecessarily obscure aspects of the present invention.

The technical proposal(s) of embodiments of the present invention will be fully and clearly described in conjunction with the drawings in the following embodiments. It will be understood that the descriptions are not intended to limit the invention to these embodiments. Based on the described embodiments of the present invention, other embodiments can be obtained by one skilled in the art without creative contribution and are in the scope of legal protection given to the present invention.

Furthermore, all characteristics, measures or processes disclosed in this document, except characteristics and/or processes that are mutually exclusive, can be combined in any manner and in any combination possible. Any characteristic disclosed in the present specification, claims, Abstract and Figures can be replaced by other equivalent characteristics or characteristics with similar objectives, purposes and/or functions, unless specified otherwise.

The present invention advantageously improves the mechanical smoothness of an antenna, metal trace(s), and/or inductor on a backplane and the electrical contact between the antenna, metal trace(s), and/or inductor and electronic circuitry. In addition, the present invention advantageously enables various attachment techniques, such as solder bumps and/or a direct solder attachment to an antenna, metal trace(s) and/or inductor without the use of an OCP or ACP. Furthermore, the present invention may reduce the cost and/or processing time of electronic devices and/or wireless tags, increases the scalability of the manufacturing process, and is compatible with food products.

An Exemplary Method of Making an Electronic Device

The present invention concerns a method of manufacturing an electronic device, comprising forming a first metal layer on a first substrate, forming an electrical device on a second substrate, forming electrical connectors on input and/or output terminals of the electrical device, selectively depositing a second metal on at least part of the first metal layer, and electrically connecting the electrical connectors to the first metal layer by contacting the electrical connectors to the second metal. The second metal is different from the first metal layer, and improves adhesion and/or electrical connectivity of the first metal layer to the electrical connectors on the electrical device. The electronic device may be a wireless communication device. In various embodiments, the wireless communications and wireless device comprises a radio frequency (RF and/or RFID), near field communication (NFC), high frequency (HF), very high frequency (VHF), ultra high frequency (UHF), or electronic article surveillance (EAS) tag and/or device. In one example, the device is an NFC device, such as an NFC tag, smart tag, or smart label.

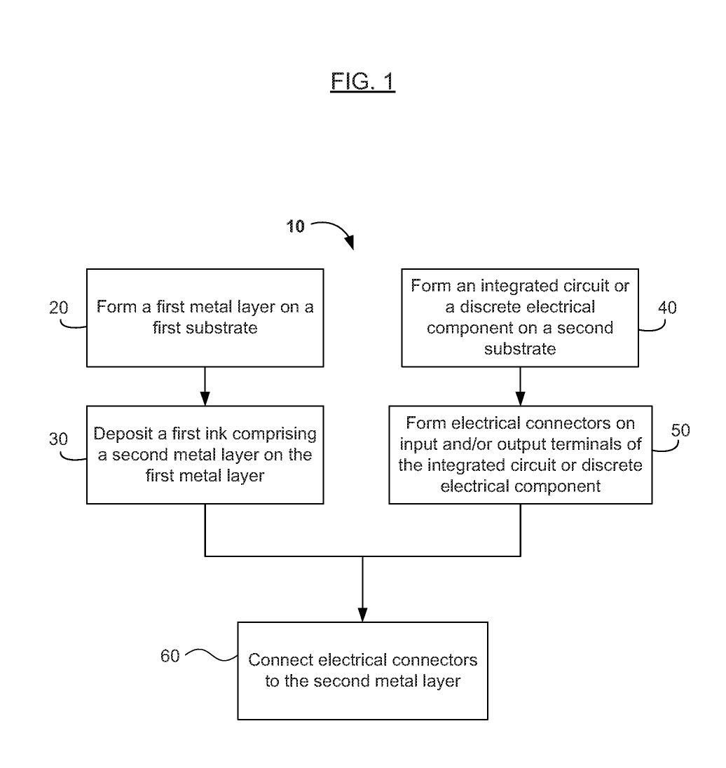

FIG. 1 shows a flow chart for an exemplary process 10 for making electronic devices (e.g., wireless communication devices, such as NFC/RF and/or EAS tags or devices) having a layer of palladium or other adhesion-promoting metal or alloy selectively deposited on part of an antenna, metal trace(s) and/or inductor, in accordance with one or more embodiments of the present invention. The palladium (or other second metal) layer advantageously improves adhesion and/or electrical connectivity of the antenna, metal trace(s) and/or inductor to the electrical device, and enables flexibility with attachment without the use of OCP or ACP. For example, the integrated circuit or electrical device may be attached to the second metal layer on the antenna, metal trace(s) and/or inductor using solder bumps or direct solder attachment.

At 20, a first metal layer is formed on a first substrate. Forming the first metal layer may comprise depositing an aluminum layer (e.g., an aluminum foil) on a first surface of the first substrate. The aluminum layer may be coated or laminated on the first substrate (e.g., a wireless or display backplane), then etched to form the antenna and/or trace(s). Generally, the aluminum layer has a thickness of at least 10 μm. The aluminum layer can also include an aluminum alloy (e.g., with 0.1-5 wt. or atomic % of one or more of copper, tin, silicon, titanium, etc.). In some embodiments, at least one trace is formed on the first substrate. More typically, forming at least one trace forms a plurality of metal traces on the first substrate. Forming the first metal layer may further comprise etching the coated or laminated aluminum layer to form an antenna, inductor and/or one or more traces on the backplane. Generally, the antenna and/or inductor is configured to (i) receive and (ii) transmit or broadcast wireless signals, and the trace(s) are configured to electronically connect an electrical device (e.g., an integrated circuit or discrete electrical component, such as a capacitor) to one or more other components (e.g., a battery, display, one or more sensors, etc.).

In some embodiments, forming the antenna, metal trace(s) and/or inductor may consist of forming a single metal layer on the first substrate, patterning the metal layer, and etching the single metal layer to form the antenna, metal trace(s) and/or inductor. For example, forming the antenna, metal trace(s) and/or inductor may comprise printing a first ink or paste (e.g., including a first metal or metal precursor) on the first substrate in a pattern corresponding to the antenna, metal trace(s) and/or inductor, then drying the first ink or paste, and curing the metal or metal precursor in the first ink or paste. Optionally, after printing, the method may further include reducing a metal precursor such as a metal salt or complex in the metal ink (e.g., by curing the metal salt or complex in a reducing atmosphere, such as forming gas). Additionally or alternatively, the method may include printing a metal seed layer by the printing process described in this paragraph, and electroplating or electrolessly plating a bulk metal on the printed metal seed layer. An exemplary antenna and/or inductor thickness for HF devices may be about 20 μm to 50 μm (e.g., about 30 μm), and may be about 10 μm to about 30 μm (e.g., about 20 μm) for UHF devices.

In various embodiments, the first substrate may comprise an insulative substrate (e.g., plastic film or glass). For example, the insulative substrate may comprise a polyimide, a glass/polymer laminate, or a high temperature polymer. The high temperature polymer may consist of polyethylene terephthalate [PET], polypropylene, or polyethylene naphthalate [PEN].

At 30, a second metal is selectively deposited on the first metal layer. In one embodiment, an ink comprising the second metal is printed on predetermined areas of the first metal layer, generally including areas or regions of the first metal layer to which electrical connectors of an integrated circuit or discrete electrical component are to be connected. The second metal ink may be identical to or different from the first metal ink. In some embodiments, the second metal comprises palladium (e.g., a palladium salt or complex) or consists essentially of palladium (e.g., elemental palladium, such as palladium nanoparticles).

In various embodiments, the second ink comprising the second metal or a precursor of the second metal may be printed on at least part of the first metal layer. The second ink may be printed or otherwise selectively deposited on predetermined areas of and/or locations on the first metal layer, but the method is not so limited. For example, the second ink may be printed or selected depending on the entire first metal layer, but not on areas or regions of the first substrate not containing the first metal layer. In exemplary embodiments, the second metal ink comprises a palladium ink, which is printed onto bonding regions or areas of the first metal layer. Palladium inks may be formulated in accordance with U.S. Pat. Nos. 8,617,992 and 8,066,805, the relevant portions of which are incorporated herein by reference. For example, a palladium ink may comprise palladium chloride, water, and a water-soluble solvent, such as tetrahydrofuran (THF), ethylene glycol, etc. Alternatively, the palladium ink may comprise palladium nanoparticles suspended in one or more organic solvents. In exemplary embodiments, the palladium ink is printed in a pattern on a surface of the first metal layer (e.g., the antenna, metal trace(s) and/or inductor). The pattern may be or correspond to bonding regions or areas of the antenna, trace(s), and/or inductor.

In one embodiment, the printed second metal ink may be dried and cured. In general, when the present method comprises printing the second ink, the method further comprises drying (or removing the solvent[s] from) the printed second metal or second metal precursor. In an exemplary embodiment, the drying process comprises heating the printed metal precursor to a temperature and/or for a length of time sufficient to remove substantially all of the solvent(s). In other embodiments, drying comprises removing the solvent(s) in a vacuum, with or without applied heat. In any such embodiments, the temperature for removing the solvent may be from 30° C. to 150° C., 50° C. to 100° C., or any value or range of values therein. The length of time may be sufficient to remove substantially all of the solvent and/or substantially all of any additive(s) from the printed second metal or second metal precursor (e.g., from 1 minute to 4 hours, 5 minutes to 120 minutes, or any other range of values therein). The vacuum may be from 1 mtorr to 300 torr, 100 mtorr to 100 torr, 1-20 torr, or any other range of values therein, and may be applied by vacuum pump, aspirator, Venturi tube, etc. Such additives may be selected from those additives that can be removed substantially completely by heating at a temperature of from room temperature to 150° C. and/or under a vacuum of from 1 mtorr to 1 atm for a length of time of from 1 minute to 8 hours, such as water, HCl, ammonia, tetrahydrofuran, glyme, diglyme, etc.

After printing and drying an ink including a precursor of the second metal (e.g., a salt or complex of the second metal), the metal precursor may be reduced by various methods. For example, the metal precursor may be exposed to a reducing agent and heated at a temperature ranging from greater than ambient temperature to about 200-400° C., depending on the substrate. Such a process has particular advantages when the substrate must be processed at a relatively low temperature (e.g., aluminum foil, a polycarbonate, polyethylene and polypropylene esters, a polyimide, etc.). A sealable oven, furnace, or rapid thermal annealing furnace configured with a vacuum source and reducing/inert gas sources may be used for providing the reducing atmosphere and heat (thermal energy) for heterogeneous reduction. In the alternative, the metal precursor film may be thermally decomposed to the elemental metal using a heat source (e.g., a hotplate) in an apparatus in which the atmosphere may be carefully controlled (e.g., a glove box or dry box). In further embodiments, the metal-containing precursor is reduced in a liquid (e.g., hydrazine in water and/or an organic solvent, or a solution of a borane, a borohydride, an aluminum hydride [e.g., LiAlH₄], etc.) or an atmosphere comprising a reducing agent in the form of a vapor, gas, or plasma source (e.g., forming gas, ammonia, hydrazine vapor, a hydrogen plasma, etc.).

Curing (e.g., by annealing) a palladium salt or complex in a palladium ink generally includes heating the dried ink in a reducing atmosphere under forming gas at a temperature of 100° C. to 250° C., preferably at a temperature of 130° C. For example, in one variation, the annealing temperature for forming palladium from the dried palladium precursor may range from 120 to 300° C. (e.g., from about 150 to about 250° C., or any temperature or range of temperatures therein). However, with possible improvements in purity, print processing, film morphology, etc., the annealing temperature for forming metal having relatively higher conductivity can be reduced to less than 100° C., and possibly even at ambient temperatures (e.g., about 25° C.).

In further embodiments, a bonding metal may be electrolessly plated on the second metal layer. When the second metal comprises palladium, it may be plated with a bonding metal such as nickel, copper, tin, silver, gold, or a combination thereof. Bonding metal adheres to the second metal and forms a strong bond to or with the electrical connectors. The palladium-containing layer may have a thickness of 3 Å to 200 Å, or any thickness or range of thicknesses therein. The bonding metal may also form an alloy or intermetallic interface with the second metal.

At 40, an electrical device is formed on a second substrate. The electrical device comprises an integrated circuit or a discrete device/electrical component (e.g., capacitor, inductor, resistor, switch, etc.). The integrated circuit may comprise a thin film integrated circuit or a printed integrated circuit (e.g., excluding a circuit formed on a monolithic single-crystal silicon wafer or die).

In various embodiments, the second substrate may comprise an insulative substrate (e.g., plastic film or glass). For example, the insulative substrate may comprise a polyimide, a glass/polymer laminate, or a high temperature polymer. The high temperature polymer may consist of polyethylene terephthalate [PET], polypropylene, or polyethylene naphthalate [PEN]. Alternatively, the second substrate may comprise a metal sheet, film or foil, or a laminate thereof. For example, the metal substrate may comprise a metal foil, such as a stainless steel foil, with one or more diffusion barrier and/or insulator films thereon. In one example, a stainless steel foil may have one or more diffusion barrier films such as a single of or multilayer TiN, AlN, or TiAlN thereon, and one or more insulator films such as silicon dioxide, silicon nitride and/or silicon oxynitride on the diffusion barrier film(s). The diffusion barrier film(s) may have a combined thickness of from 300 Å to 5000 Å (e.g., 300-950 Å, or any thickness or range of thicknesses between 300 Å and 5000 Å), and the insulator film(s) may have a combined thickness of from 200 Å to 5000 Å (e.g., 250-2000 Å, or any thickness or range of thicknesses between 200 Å and 5000 Å). The insulator film(s) may have a thickness sufficient to electrically insulate electrical devices formed thereon from the underlying metal substrate and diffusion barrier layer(s).

Forming the integrated circuit or discrete device may comprise printing one or more layers of the integrated circuit or discrete device on the second substrate. An integrated circuit having one or more layers therein formed by printing may be considered to be a printed integrated circuit, or PIC.

In an exemplary method, a plurality of the layers of the integrated circuits may be printed, in which a lowermost layer (e.g., a lowermost insulator, conductor, or semiconductor layer) may be printed or otherwise formed on the second substrate. The lowermost layer of material is advantageously printed to reduce issues related to topographical variations in the integrated circuit layer(s) on the second substrate. Alternatively, a different (e.g., higher) layer may be printed. Printing offers advantages over photolithographic patterning processes, such as low equipment costs, greater throughput, reduced waste (and thus, a “greener” manufacturing process), etc., which can be ideal for relatively low transistor-count devices such as NFC, RF and HF tags.

In one example, input and/or output terminals may be formed in an uppermost layer of the integrated circuit by a printing technique (e.g., screen printing, inkjet printing, gravure printing, etc.). The first input and/or output terminal may be at a first end of the integrated circuit or discrete device, and the second input and/or output terminal may be at a second end of the integrated circuit or discrete device opposite from the first end. In exemplary embodiments, the input and/or output terminals comprise first and second antenna connection pads. The material of the input and/or output terminals may include aluminum, tungsten, copper, silver, etc., or a combination thereof (e.g., a tungsten thin film on an aluminum pad).

Alternatively, the method may form one or more layers of the integrated circuit by one or more thin film processing techniques. Thin film processing also has a relatively low cost of ownership, and is a relatively mature technology, which can result in reasonably reliable devices being manufactured on a wide variety of possible substrates. Thus, in some embodiments, the method may comprise forming a plurality of layers of the integrated circuitry by thin-film processing techniques (e.g., blanket deposition, photolithographic patterning, etching, etc.). In an alternative example, input and/or output terminals may be formed in an uppermost metal layer of the integrated circuit by thin-film processing.

In some embodiments, both printing and thin film processing can be used, and the method may comprise forming one or more layers of the integrated circuit by thin film processing, and printing one or more additional layers of the integrated circuit. In some embodiments, a plurality of integrated circuits may be formed on the second substrate, then singulated or otherwise separated prior to attachment to the antenna, metal trace(s), and/or inductor.

The discrete device (e.g., the capacitor or other discrete electrical component) may be printed or otherwise formed on the second substrate. When forming a capacitor, the method may comprise forming a first capacitor electrode or plate on the second substrate, forming a dielectric layer on or over the first capacitor electrode or plate, and forming a second capacitor electrode or plate on the dielectric layer. Details of forming capacitor structures by various techniques may be found in U.S. Pat. Nos. 7,152,804, 7,286,053, 7,387,260, and 7,687,327, and U.S. patent application Ser. No. 11/243,460 filed Oct. 3, 2005 [Atty. Docket No. IDR0272], the relevant portions of each of which are incorporated herein by reference.

At 50, electrical connectors may be formed on the input and/or output terminals of the integrated circuit or discrete device (e.g., a capacitor). The electrical connectors may be formed, for example, by printing (e.g., screen printing) a paste of an electrically conductive material onto the input and/or output terminals. In various examples, the electrical connectors may comprise solder bumps or solder balls on the input and/or output terminals of the integrated circuit or discrete device. The solder bumps or solder balls may include a solder alloy (e.g., tin and one or more alloying elements), and may be deposited (e.g., by screen printing) on the input and/or output terminals. The alloying element(s) may be selected from bismuth, silver, copper, zinc, and indium. The solder bumps or solder balls may further contain an adhesive resin that may be activated by heating (e.g., to the solder reflow temperature or less), such as an epoxy resin. Some materials that include both a solder alloy and a resin include a SAM resin (e.g., SAM10 resin, available from Tamura Corporation, Osaka, JP) and/or self-alignment adhesives with solder (SAAS) and/or SAM resins that are commercially available from Panasonic Corporation, Tokyo, JP; Namics Corporation, Niigata City, JP; and Nagase & Co., Ltd., Tokyo, JP.

Typically, a first solder bump or solder ball is on a first input and/or output terminal, and a second solder bump or solder ball on a second input and/or output terminal. Thus, solder bumps or solder balls may be used to advantageously attach the electrical device (e.g., the integrated circuit or discrete device) to the combined first and second metal (e.g., palladium on aluminum) layers of the antenna, metal trace(s), and/or inductor. In a further embodiment, an ACP may be deposited on the solder bumps or solder balls and/or the input and/or output terminals not covered by the solder bumps or solder balls to further adhere and/or electrically connect the IC or discrete device to the antenna, metal trace(s) and/or inductor, but an ACP is not necessary in this invention. Additionally or alternatively, a non-conductive adhesive may be deposited on the first substrate in areas other than second metal layer. For example, the adhesive may include an epoxy non-conductive paste.

At 60, the electrical connectors are connected to the second metal layer or a metal or alloy plated thereon. Methods of placing the electrical device on or over the palladium-plated antenna and/or inductor include, but are not limited to, pick-and-place processing and roll-to-roll processing. Methods of attaching the electrical device to the palladium-plated antenna and/or inductor include, but are not limited to, crimping, applying an adhesive (e.g., an epoxy paste) on the electrical device (e.g., in areas other than the antenna connection pads), and/or pressing the electrical device to the antenna, trace or inductor.

In some embodiments, electrically connecting the electrical connectors to the second metal layer may comprise heating and pressing the first and second solder bumps or balls to the second metal layer at first and second locations of the antenna, metal trace(s), and/or inductor. Pressure may be applied using a conventional bonder (e.g., available from Muhlbauer High Tech International, Roding, Germany) at a pressure of about 0.1N to about 50N (e.g., about 1N) for a second substrate having a surface area of about 0.5 mm² to about 10 mm² (e.g., 1.5 mm² to about 5 mm², and in one example, about 2.25 mm²). When the antenna, metal trace(s) and/or inductor includes a bulk aluminum layer, the IC or capacitor on the second substrate may be pressed into the antenna, metal trace(s) and/or inductor (on the first substrate) with a heated pressing tool. Thus, optionally, heating may be applied simultaneously with the pressure to the first and second substrates using a thermal head. The target temperature generally depends on the substrate materials, but can generally be from 50° C. to about 400° C. For example, when using a PET substrate, a maximum temperature of 190° C. should be used. However, 190° C. may also be a minimum temperature for curing certain adhesives, in which case a substrate that can tolerate higher temperatures should be used.

When metal traces are formed on the first substrate, a sensor, a battery and/or a display may be attached to one or more of the traces (as may the IC) and electrically connected to the electrical device using at least one connector. Generally, each of the sensor, battery and/or display are connected to a unique set of traces using a matching or corresponding set or plurality of electrical connectors. Each of the traces is also connected to one or more unique input and/or output terminals of the IC and/or other electrical component (e.g., battery, memory, etc.). The traces may be formed from the first and/or second metal layers. Thus, the traces comprise one or more of the same materials as the antenna and/or inductor (e.g., aluminum with palladium printed thereon, or a palladium seed layer with a bulk metal layer plated thereon), and are formed similarly to the antenna and/or inductor. In some embodiments, the metal trace(s) may comprise a printed palladium seed layer with a third metal plated (e.g., electroplated or electrolessly plated) on the seed layer. The third metal may be or comprise a noble metal (e.g., copper, silver, or gold), a transition metal (e.g., nickel, chromium, tungsten, molybdenum, etc.), or other metal (e.g., tin or zinc). Furthermore, other components in addition to the sensor, battery, and/or display may be attached to the substrate and/or the metal trace(s) using any of a variety of surface mounted device (SMD) attachment techniques.

Exemplary Electronic Devices and Intermediates in an Exemplary Process for Manufacturing the Same

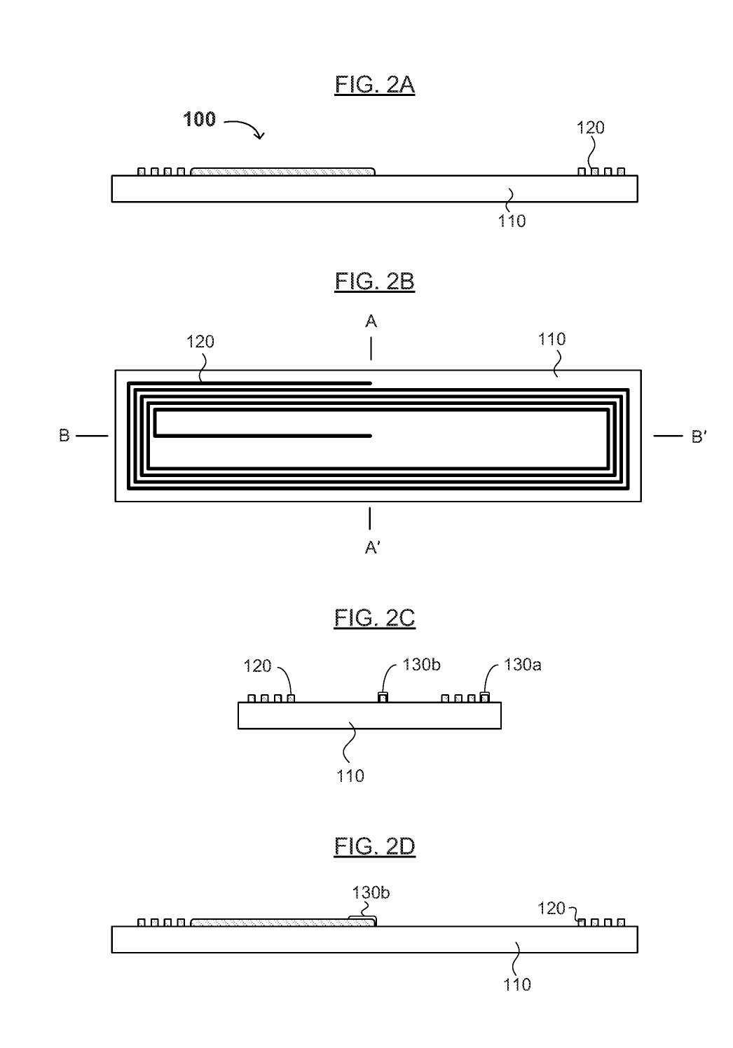

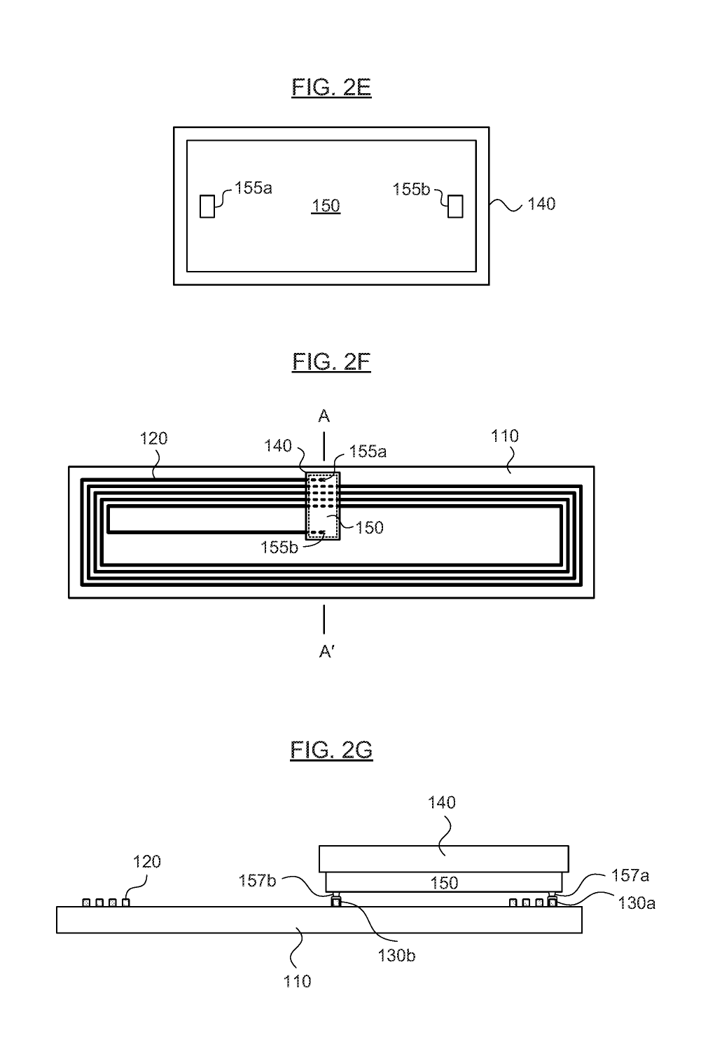

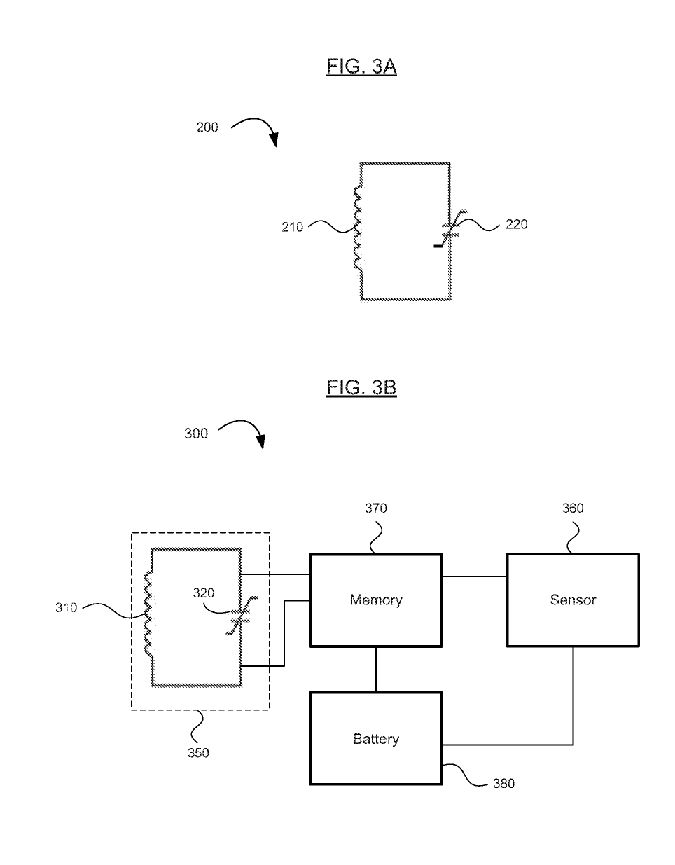

FIGS. 2A-2E show plan and cross-sectional views of exemplary intermediates in the exemplary process, and FIGS. 2F-2G show plan and cross-sectional views of an exemplary electronic device having a surface layer of palladium on an aluminum antenna, in accordance with one or more embodiments of the present invention.

The electronic device generally includes a substrate having first and second metal layers (e.g., palladium on aluminum) thereon, and an electrical device (e.g., an integrated circuit or a discrete device or electrical component, such as a capacitor) on a second substrate. The integrated circuit or discrete device includes electrical connectors on input and/or output terminals thereof, and is configured to (i) process a first signal and/or information therefrom, and (ii) generate a second signal and/or information therefor. The electrical connectors are electrically connected to at least the second metal layer on the first substrate. The second metal layer is configured to improve the adhesion and/or electrical connectivity of the first metal layer to the electrical connectors.

In some embodiments, the integrated circuit may comprise a thin film integrated circuit or a printed integrated circuit (e.g., excluding a circuit formed on a monolithic single-crystal silicon wafer or die), and the discrete device or discrete electrical component may comprise or consist of a capacitor, an inductor, a resistor, a switch, etc. In further or other embodiments, the electronic device may be a wireless communication device.

FIG. 2A shows a first substrate 110 having a first metal layer 120 thereon. In various embodiments, the first substrate 110 may comprise an insulative substrate (e.g., plastic film or glass). For example, the insulative substrate 110 may comprise a polyimide, a glass/polymer laminate, or a high temperature polymer. The high temperature polymer may comprise or consist of polyethylene terephthalate [PET], polypropylene, or polyethylene naphthalate [PEN], for example, but is not limited thereto.

In various embodiments, the first metal layer 120 may comprise a patterned aluminum layer (e.g., a patterned aluminum foil) on a first surface of the first substrate 110. The aluminum layer may consist essentially of elemental aluminum or may comprise or consist essentially of an aluminum alloy (e.g., aluminum with one or more alloying elements such as copper, titanium, silicon, magnesium, manganese, tin, zinc, etc.). Generally, the aluminum layer 120 has a thickness of at least 10 μm.

FIG. 2B shows an antenna and/or inductor 120 corresponding to the first metal layer 120 of FIG. 2A. FIG. 2A shows a cross-section of FIG. 2B along the B-B′ line. Generally, the antenna and/or inductor 120 is configured to (i) receive and (ii) transmit or broadcast wireless signals. Alternatively, the antenna and/or inductor 120 absorbs part of an electromagnetic signal broadcast from a radiation source (such as a wireless reader), or backscatters electromagnetic radiation from such a radiation source at a different wavelength. In some embodiments, the antenna and/or inductor 120 may consist of a single metal layer on the first substrate 110. An exemplary antenna and/or inductor thickness for HF devices may be about 20 μm to 50 μm (e.g., about 30 μm), and may be about 10 μm to about 30 μm (e.g., about 20 μm) for UHF devices. Although FIG. 2B shows a spiral antenna having four loops, the antenna may more than four loops or less than four loops, and may have any of several forms, such as serpentine, sheet or block (e.g., square or rectangular), triangular, etc.

In various embodiments, the antenna and/or inductor 120 may be a printed antenna and/or inductor (e.g., using a printed conductor such as, but not limited to, silver or copper from a paste or nanoparticle ink) or a photolithographically-defined and etched antenna and/or inductor (e.g., formed by sputtering or evaporating aluminum on a substrate such as a plastic film or sheet, patterning by low-resolution [e.g., 10-1,000 μm line width] photolithography, and wet or dry etching using the patterned photolithography resist as a mask). The printed antenna, traces, and/or inductor may have a line with of from about 50 μm to about 5000 μm, and may have a crystal morphology different from that of a photolithographically-defined and etched antenna, trace or inductor, a more rounded cross-section than a photolithographically-defined and etched antenna, metal trace or inductor, and/or a surface roughness, edge uniformity and/or line width uniformity that is generally greater than a photolithographically-defined and etched antenna, metal trace or inductor. The antenna and/or inductor 120 may have a size and shape that matches any of multiple form factors, while preserving compatibility with the target frequency or a frequency specified by one or more industry standards (e.g., the 13.56 MHz target frequency of NFC reader hardware).

FIG. 2C shows a cross section of the first substrate 110 along line A-A′ in FIG. 2B, in which an exemplary second metal layer 130a, 130b is on the first metal layer 120. In exemplary embodiments, the second metal layer 130a, 130b comprises an adhesion-promoting metal or alloy, such as palladium (e.g., a palladium layer). Preferably, the second metal layer 130a, 130b is printed or otherwise selectively deposited on the ends (e.g., first and second ends, respectively) of the antenna 120. The selectively-deposited second metal regions 130a, 130b serve as connection points to the integrated circuit or discrete device, which advantageously minimizes the amount and cost associated with palladium ink. Alternatively, the second metal layer 130 may comprise a printed palladium layer on which a bonding metal, such as nickel, copper, tin, silver, gold, or an alloy or combination thereof, is electrolessly plated. Those skilled in the art can determine conditions for electrolessly plating such bonding metals selectively onto the second metal (e.g., palladium), without plating the bonding metal onto the first metal (e.g., aluminum).

FIG. 2D shows a cross-section along the line B-B′ in FIG. 2B. The second metal layer 130b is on only an internal end of the antenna and/or inductor 120. The dimensions of the printed second metal layer 130 may depend on the dimensions of the antenna/inductor 120 (or trace when present) and/or the electrical connector. For example, the width of the second metal layer 130 may be at least the width of the antenna and/or inductor 120 plus two times an alignment margin for selectively depositing the second metal layer 130a (e.g., 60-5,500 μm). The length of the second metal layer 130 may be at least the width, length or diameter of the electrical connector (whichever is greatest) plus two times the alignment margin for placing the electrical device on the first substrate. This length can be, e.g., up to 3-5 times the width, length, or diameter of the electrical connector.

FIG. 2E shows an electrical device 150 on a second substrate 140. The electrical device 150 includes an integrated circuit or a discrete device. In various embodiments, the second substrate 140 comprises a metal foil. In one example, the metal foil comprises a stainless steel foil, as described herein. Alternatively, the metal foil comprises an aluminum foil, a tin foil, a molybdenum foil, etc. When the second substrate 140 is a metal foil, it may be coated with one or more barrier and/or insulator layer(s), as described herein. Alternatively, the second substrate may comprise a plastic film or a glass sheet or slip, as described herein.

In various embodiments, when the electrical device 150 includes the integrated circuit, and when the integrated circuit is a wireless communication device, the integrated circuit 150 may comprise a receiver and/or transmitter. The transmitter may comprise a modulator configured to generate a wireless signal to be broadcast by the assembled electronic device, and the receiver may comprise a demodulator configured to convert the wireless signal received by the assembled electronic device to one or more electrical signals (e.g., to be processed by the electrical device 150).

In some embodiments, the integrated circuit 150 may include one or more printed layers. Such layers have characteristics of printed materials, such as greater dimensional variability, a thickness that varies (e.g., increases) as a function of distance from the edge of the printed structure, a relatively high surface roughness, etc. Additionally and/or alternatively, the integrated circuit 150 may (further) comprise one or more thin films (e.g., a plurality of thin films).

Alternatively, the electrical device 150 may comprise or consist of a discrete device on the second substrate 140, as described herein. The discrete device 150 may be or comprise a capacitor, a resistor, a switch, an inductor, etc. For example, the capacitor may comprise a first capacitor electrode or plate on the second substrate 140, a dielectric layer on the first electrode or plate, and a second capacitor electrode or plate on the dielectric layer. Alternatively, the capacitor may comprise first and second electrodes or plates on the second substrate 140 with the dielectric therebetween.

Generally, the integrated circuit or discrete device/electrical component 150 further includes input/output terminals or connection pads 155a-b at ends of the discrete device (e.g., at a first tab or bonding area electrically connected to the first capacitor electrode or plate, and a second tab or bonding area electrically connected to the second capacitor electrode or plate). In exemplary embodiments, the uppermost metal layer of the electrical device 150 includes the input and/or output terminals 155a-b. If the electrical device 150 is a discrete device, the discrete device may include input and/or output terminals electrically connected to electrodes or electrode terminals of the discrete device. The first input and/or output terminal 155a may be at a first end of the electrical device 150, and the second input and/or output terminal 155b may be at a second end of the electrical device 150 opposite from the first end. In various embodiments, the input and/or output terminals 155a, 155b on the electrical device 150 may include antenna and/or inductor connection pads 155a, 155b. The input and/or output terminals 155a, 155b may comprise aluminum, tungsten, copper, silver, etc., or a combination thereof, and may have one or more barrier and/or adhesion-promoting layers thereon. For example, the input and/or output terminals 155a, 155b may comprise a bulk aluminum layer with a thin tungsten adhesion and/or oxygen barrier layer thereon.

FIG. 2F shows the electrical device 150 on the second substrate 140 connected to the antenna, metal trace(s) and/or inductor 120 on the first substrate 110. Electrical connectors 157a, 157b are on input and/or output terminals of the electrical device 150. In exemplary embodiments, the first and second antenna connection pads 155a, 155b and the electrical device 150 electrically connect the ends of the antenna 120 to each other. As a result, the second substrate 140 may function as an interposer that bridges the ends of the antenna 120 and provides an insulating mechanical support for the electrical component(s) that is/are electrically connected to the ends of the antenna 120.

FIG. 2G shows a cross-section of the electronic device along line A′-A in FIG. 2F, in which the antenna and/or inductor 120 is attached to the electrical device 150 through the second metal layer 130a, 130b and the electrical connectors 157a, 157b on the input and/or output terminals 155a, 155b on the electrical device 150. The electrical connectors 157a, 157b may comprise solder bumps or solder balls. Solder bumps or solder balls 157a, 157b may include a solder alloy (e.g., tin and one or more alloying elements as described herein). For example, the alloying elements may be selected from bismuth, silver, copper, zinc, and indium. Typically, a first solder bump or solder ball 157a is on a first input and/or output terminal 155a, and a second solder bump or solder ball 157b is on a second input and/or output terminal 155b. Electrical connectors 157a, 157b may further comprise an adhesive (e.g., epoxy) that adheres or anchors the solder bump or solder ball to the input/output terminal 155a or 155b.

In some embodiments, at least one trace (not shown) is also on the first substrate 110. A sensor, a battery and/or a display may be attached to one or more of the traces (typically, a plurality of the traces) and electrically connected to the electrical device 150 (and, optionally, to another of the sensor, battery and/or display, such as the battery). The traces may comprise the first metal layer 120 and the second metal layer 130 in locations corresponding to regions of the metal layer 120 to which electrical connections are to be made. The sensor may be configured to sense an environmental parameter, such as temperature or relative humidity, or a continuity state of packaging onto which the backplane 110, electrical device 150, and sensor are attached. The display may be a relatively simple monochromatic display, configured to display relatively simple data (e.g., a 2- or 3-digit number corresponding to the sensed parameter) and/or one of a limited number of messages (e.g., “Valid” or “Not Valid,” depending on the value of the parameter relative to a predetermined minimum or maximum threshold, or “Sealed” or “Open,” depending on the continuity state of the packaging). Furthermore, other components in addition to the sensor, battery, and/or display may be attached to the substrate and/or the palladium-plated aluminum layer 120/130 using any of a variety of SMD techniques.

Exemplary EAS Tags, Wireless Devices, and Sensors

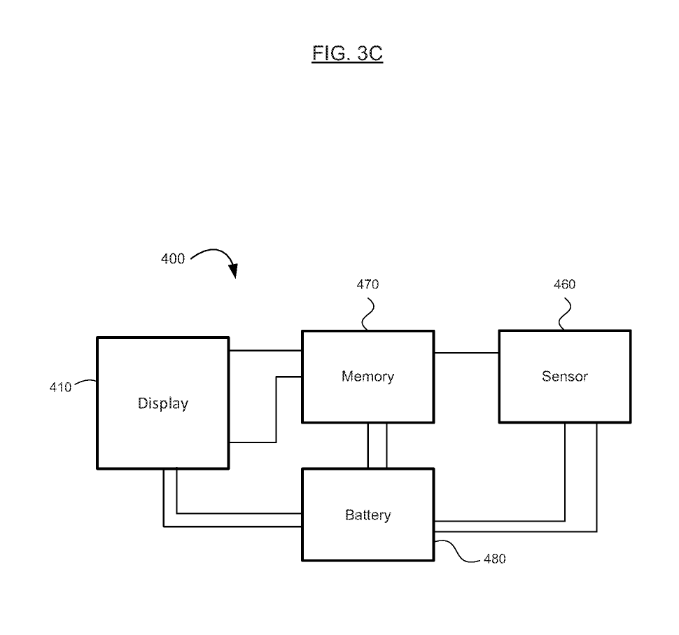

FIGS. 3A-C show exemplary circuits 200, 300 and 400 for an EAS tag, wireless device and sensor suitable for use in the present invention. FIG. 3A shows an exemplary resonant circuit 200 suitable as a surveillance and/or identification device (e.g., EAS tag). Generally, the EAS tag 200 includes an inductor (e.g., an inductor coil) 210 and a capacitor 220. The capacitor 220 may be linear (as shown) or non-linear, in which case it may further include a semiconductor layer, which may be on or in contact with at least a portion of the capacitor dielectric layer and/or a capacitor electrode. In some embodiments, the resonant circuit 200 may further comprise a second capacitor coupled with the first capacitor.

FIG. 3B shows an exemplary wireless device 300 with a resonant circuit 350 and a sensor 360, suitable for use in the present invention. The resonant circuit 350 includes an inductor 310 and a capacitor 320, and the wireless device 300 further includes a memory 370 and a battery 380 that powers the memory 370 and the sensor 360. Details of the inductor 310 and capacitor 320 are the same as or similar to the descriptions herein of inductors/antennas and capacitors, respectively. The sensor 360 may comprise an environmental sensor (e.g., a humidity or temperature sensor), a continuity sensor (e.g., that determines a sealed, open, or damaged state of the package or container to which the tag is attached), a chemical sensor, a product sensor (e.g., that senses or determines one or more properties of the product in the package or container to which the device 300 is attached), etc., and outputs an electrical signal to the memory 370. This electrical signal corresponds to the condition, state or parameter sensed or detected by the sensor 360. Typically, the memory 370 can be static or dynamic, volatile and/or non-volatile, programmed or programmable, etc. The memory 370 stores a plurality of bits of data, at least one of which corresponds to the condition, state or parameter sensed or detected by the sensor 360, and a subset of which may correspond to an identification number or code for the product to which the device 300 is attached. In some embodiments, the memory 370 and the sensor 360 may be connected to an external ground plane (not shown). The memory 370 outputs a data signal that can be read by an external reader. Thus, the reader is capable of detecting a state, condition or parameter value defined by the sensor, as well as an initial state of the memory 370. Additional circuitry can be added to the circuit 300 to change the state of the memory 370.

FIG. 3C shows an exemplary circuit 400 for a “smart label,” with a sensor 460 and a display or display panel 410 suitable for use in the present invention. The circuit 400 also includes a memory 470 and a battery 480 that powers the display 410, the memory 470, and the sensor 460. Details of the memory 470, the battery 480, and the sensor 460 are as described herein (e.g., with regard to FIG. 3B). Connections between the battery 480 and the display 410, the memory 470, and the sensor 460 may include two or more wires or traces. The display 410 is an output device configured to display a readout of signals and/or information from the memory 470. Generally, the display 410 may include an analog or digital display, a full-area 2-dimensional display, and/or a three-dimensional display, but is not limited thereto. Connections between the sensor 460 and the memory 470 may include one or more wires or traces, and the connection between the memory 470 and the display 410 may include two or more wires or traces.

### CONCLUSION

The present electronic device and method of manufacturing the same advantageously improves the mechanical smoothness (e.g., for adhesion) and electrical contact or connectivity of metals commonly used for antennas, metal traces and/or inductors on thin film or printed integrated circuit or discrete device backplanes. In addition, the present invention advantageously enables various attachment techniques, such as solder bumps on an antenna, metal trace(s) and/or inductor or a direct solder attachment, without the use of OCP or ACP techniques. Thus, a variety of components, such as discrete capacitors, inductors, or switches, can be assembled with solder, which is robust and reliable. Furthermore, the present invention further advantageously enables various attachment techniques, minimizing cost and increasing manufacturing processes.

The foregoing descriptions of specific embodiments of the present invention have been presented for purposes of illustration and description. They are not intended to be exhaustive or to limit the invention to the precise forms disclosed, and obviously many modifications and variations are possible in light of the above teaching. The embodiments were chosen and described in order to best explain the principles of the invention and its practical application. It is intended that the scope of the invention be defined by the claims appended hereto and their equivalents.

1. A method of manufacturing an electronic device, comprising:
a) forming a first metal layer on a first substrate;
b) forming an electrical device on a second substrate;
c) forming electrical connectors on input and/or output terminals of said electrical device;
d) selectively depositing a second metal on at least part of said first metal layer, said second metal improving adhesion and/or electrical connectivity of said first metal layer to said electrical connectors on said electrical device, and second metal being different from said first metal; and
e) electrically connecting said electrical connectors to said first metal layer by contacting said electrical connectors to said second metal.

2. The method of claim 1, wherein said electronic device is a wireless communication device.

3. The method of claim 1, wherein said electrical device comprises a capacitor or an integrated circuit.

4. The method of claim 1, wherein said first substrate comprises a plastic film.

5. The method of claim 1, wherein forming said first metal layer comprises depositing an aluminum layer on said first substrate.

6. The method of claim 1, wherein forming the first metal layer comprises (i) printing a first ink comprising a seed metal on the first substrate in a pattern corresponding to an antenna, one or more metal traces and/or an inductor, and (ii) electroplating or electrolessly plating a bulk metal on the printed seed metal, wherein at least one of the bulk metal and the seed metal is the first metal.

7. The method of claim 1, wherein selectively depositing said second metal comprises printing a second ink comprising the second metal or a precursor thereof on parts of said first metal layer to which said electrical connectors are to be electrically connected.

8. The method of claim 1, comprising electrolessly plating a third metal comprising nickel, copper, tin, silver, gold, or a combination thereof on said second metal.

9. The method of claim 1, wherein said electrical connectors comprise (i) a first solder bump or solder ball on a first one of said input/output terminals and (ii) a second solder bump or solder ball on a second one of said input/output terminals, and electrically connecting said electrical connectors to said first metal layer comprises heating and pressing said first and second solder bumps or solder balls to the second metal.

10. An electronic device, comprising:
a) a substrate having a first metal layer thereon;
b) an electrical device on a second substrate, said electrical device having input and/or output terminals and electrical connectors thereon, said electrical connectors being electrically connected to said first metal; and
c) a second metal on at least part of said first metal layer, said second metal improving adhesion and/or electrical connectivity of said first metal layer to said electrical connectors.

11. The electronic device of claim 10, wherein said electronic device comprises a wireless communication device.

12. The electronic device of claim 10, wherein said electrical device comprises a discrete device or an integrated circuit.

13. The electronic device of claim 10, wherein said first substrate comprises a plastic film.

14. The electronic device of claim 10, wherein said first metal layer comprises an aluminum layer.

15. The electronic device of claim 10, wherein said second metal comprises palladium.

16. The electronic device of claim 15, further comprising a third metal comprising nickel, copper, tin, silver, gold, or a combination thereof on said second metal.

17. The electronic device of claim 10, wherein said second substrate comprises a metal foil or a plastic.

18. The electronic device of claim 10, wherein the electrical connectors comprise a first solder bump or solder ball on a first one of said input and/or output terminals, and a second solder bump or solder ball on a second one of said input and/or output terminals.
